(19) United States
(12) Patent Application Publication
(10) Pub. No.: US 2014/0299507 A1
(43) Pub. Date: Oct. 9, 2014

(54) Paper Packaging Box

(71) Applicant: AU Optronics Corporation, Hsin-Chu (TW)

(72) Inventors: Li-Wei CHANG, HSIN-CHU (TW); Pei-Lun CHIEN, HSIN-CHU (TW); Hsueh-Hui LIN, HSIN-CHU (TW)

(73) Assignee: AU Optronics Corporation, Hsin-Chu (TW)

(21) Appl. No.: 14/246,638

(22) Filed: Apr. 7, 2014

(30) Foreign Application Priority Data
Apr. 8, 2013 (CN) 201310119414.1

(51) Int. Cl. H05K 13/00

(52) U.S. Cl. CPC H05K 13/0069
USPC 206/707

(57) ABSTRACT

A paper packaging box is disclosed. The paper packaging box includes a bottom cover, two side frames, a plurality of first Velcro portions, a plurality of second Velcro portions, and a top cover. The two side frames are respectively disposed standing on two opposite sides of the bottom cover. Each of the side frames has a plurality of slots, and the slots of the two side frames are face to face in pairs. The first Velcro portions are disposed at the bottom cover. The second Velcro portions are disposed at the side frames. The first Velcro portions and the second Velcro portions are engaged with each other to allow the side frames to stand on the bottom cover. The top cover is disposed above the side frames.

### RELATED APPLICATIONS

This application claims priority to Chinese Application Serial Number 201310119414.1, filed Apr. 8, 2013, which is herein incorporated by reference.

### BACKGROUND

1. Field of Invention

The present invention relates to a packaging material. More particularly, the present invention relates to a paper packaging box.

2. Description of Related Art

For high-precision and vulnerable electronic components, since they tend to be damaged by negative environmental factors, such as moisture, dust, and impact force, etc., during transportation, the requirements for their packaging structure must be strict. To decrease the damage rate of products during transportation, the protective packaging structure must have basic functions such as anti-moisture, anti-dust, and anti-vibration. Currently, the common practice is to put paper or plastic linings, and buffer materials such as plastic foam fillers or foam buffer pads, in the packaging box to space apart products. At the same time, products are prevented from colliding with walls of packaging box due to vibrations caused by transportation so as to protect contents in the packaging box. The material of plastic linings, plastic foam fillers, and foam buffer pads is usually expanded polyethylene (EPE) or polyvinyl chloride (PVC).

However, with increasing environmental awareness, to utilize such plastic linings, plastic foam fillers, and foam buffer pads will have significant impacts on environment and ecology, which does not meet environmental requirements.

In addition, when assembling the buffer materials with an electronic product, the buffer materials and the electronic product need to be first held by both hands according to the prior art. Then the electronic product packaged with buffer materials is placed into the outer packaging box. With such a process, the time required by a total packaging flow of placing an electronic product into the outer packaging box is prolonged to waste manpower and cost.

### SUMMARY

The present invention provides a paper packaging box that enables easy assembly.

An aspect of the invention provides a paper packaging box. The paper packaging box comprises a bottom cover, two side frames, a plurality of first Velcro portions, a plurality of second Velcro portions, and a top cover. The two side frames are respectively disposed standing on two opposite sides of the bottom cover. Each of the side frames comprises a plurality of slots, and the slots of the two side frames are disposed face to face in pairs. The plurality of first Velcro portions are disposed at the bottom cover. The plurality of second Velcro portions are disposed at the side frames. The first Velcro portions and the second Velcro portions are engaged with each other to allow the side frames to stand on the bottom cover. The top cover is disposed above the side frames.

In the foregoing, each of the side frames comprises a bottom plate, a side plate, and a plurality of first spacing boards. The plurality of first spacing boards are disposed approximately perpendicular to the side plate. Each of the first spacing boards is approximately parallel with the other first spacing boards. The slots are formed between the adjacent first spacing boards.

In the foregoing, the bottom plate and the side plate are integrally formed.

In the foregoing, the side plate comprises a body and two bending portions. One ends of the two bending portions are respectively connected to opposite ends of the body. Another ends of the two bending portions are respectively connected to two opposite ends of the bottom plate.

In the foregoing, the side frame comprises at least one reinforcement sheet attached to top ends of the body and the bending portions or bottom ends of the body and the bending portions.

In the foregoing, the bottom cover comprises a positioning hole. The side frame comprises a positioning protrusion projecting from the bottom plate. The positioning hole is utilized for engaging with the positioning protrusion.

In the foregoing, the second Velcro portions are disposed at the bottom plate.

In the foregoing, the bottom plate comprises a plurality of first alignment points. The bottom cover comprises a plurality of second alignment points. The second alignment points are utilized for aligning with the first alignment points so as to position the side frame on the bottom cover.

In the foregoing, the side plate comprises at least one center alignment structure. The center alignment structure is disposed in such a manner that a position of the center alignment structure corresponds to at least one center slot of the slots.

In the foregoing, the bottom cover comprises a base plate, a plurality of extending portion, and a plurality of third Velcro portions and a plurality of fourth Velcro portions. The first Velcro portions are disposed on the base plate. The plurality of extending portions are connected to sides of the base plate. The plurality of third Velcro portions and the plurality of fourth Velcro portions are disposed on the extending portions. The extending portions are fastened together through the engagement between the third Velcro portions and the fourth Velcro portions when the extending portions stand on the base plate.

In the foregoing, the paper packaging box further comprises a frame retaining wall utilized for being mounted outside the side frames.

In the foregoing, a height of the frame retaining wall is greater than a height of the side frames.

In the foregoing, the top cover and the bottom cover respectively cover two opposite sides of the frame retaining wall.

In the foregoing, the paper packaging box further comprises two spacers disposed in the frame retaining wall. Each of the spacers comprises a top plate and a plurality of second spacing boards disposed approximately perpendicular to the top plate. Accommodation spaces corresponding to the slots of the side frame are formed between the adjacent second spacing boards.

In the foregoing, the paper packaging box further comprises a top buffer material and a bottom buffer material. The top buffer material is disposed between the spacers and the top cover. The bottom buffer material is disposed on the bottom cover.

The present invention paper packaging box is made of a hard paper material, such as corrugated board. Not only is the present invention paper packaging box environmentally friendly, but the transportation quantity is also increased owing to the reduced spacing between the slots. In addition, since the paper packaging box is assembled by utilizing Velcro, it has the advantages of easy assembly and simple placement.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is an exploded view of a paper packaging box according to one embodiment of this invention;

FIG. 2 is a schematic diagram of a paper packaging box when a side frame is assembled with a bottom cover according to one embodiment of the invention;

FIG. 3 is a schematic diagram of a spacer in a paper packaging box in service state according to one embodiment of the invention; and

FIG. 4A to FIG. 4C are perspective views of a paper packaging box at different assembly stages according to the invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

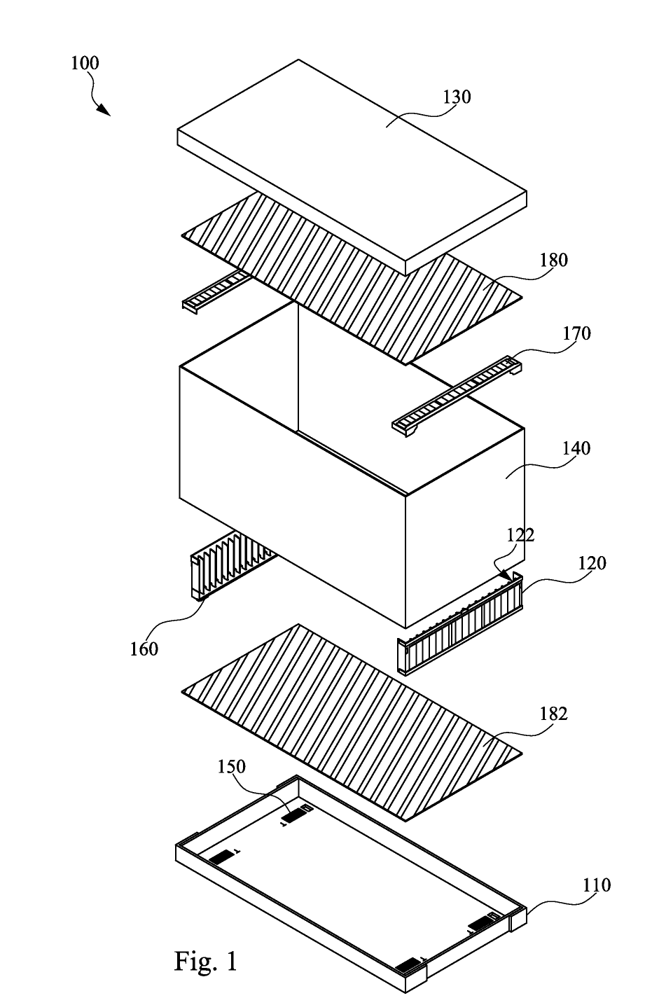

FIG. 1 is an exploded view of a paper packaging box according to one embodiment of this invention. The paper packaging box 100 comprises a bottom cover 110, two side frames 120, a top cover 130, and a frame retaining wall 140. The side frames 120 are respectively disposed standing on two opposite sides of the bottom cover 110. Each of the side frames 120 has a plurality of slots 122, and the slots 122 of the two side frames 120 are face to face in pairs. A plurality of accommodation spaces are thus formed between the side frames 120 for accommodating plate-shaped objects, such as a flat panel display or a solar module.

Each of the side frames 120 may be connected to the bottom cover 110 through a detachable adhesive structure to allow the side frames 120 to stand on the bottom cover 110. In greater detail, a plurality of first Velcro portions 150 are disposed at the bottom cover 110, and a plurality of second Velcro portions 160 are disposed at a bottom of each of the side frames 120. The first Velcro portion 150 and the second Velcro portion 160 may be two portions of Velcro, respectively. For example, the first Velcro portion 150 comprises many tiny loops, and the second Velcro portion 160 comprises many tiny hooks. Or, the first Velcro portion 150 comprises many tiny hooks, and the second Velcro portion 160 comprises many tiny loops. The first Velcro portions 150 and the second Velcro portions 160 may be attached to the bottom cover 110 and the side frames 120 by using adhesive. A shape of the first Velcro portion 150 and the second Velcro portion 160 may be a strip. A size of the first Velcro portion 150 may be the same as or different from a size of the second Velcro portion 160. Since the first Velcro portions 150 are fastened to the second Velcro portions 160 through the mutual engagement between loops and hooks, the only action required is to place the side frames 120 on the bottom cover 110 with the side frames 120 aligning with the predetermined assembled positions_when the side frames 120 are assembled with the bottom cover 110. With such a configuration, no other fixing member is required. As a result, the assembly efficiency of side frames 120 is improved.

After the side frames 120 are fixed to the bottom cover 110, the plate-shaped objects to be placed are put into the accommodation spaces defined by the slots 122 of the two side frames 120. The frame retaining wall 140 is then disposed around the outside of the side frames 120 and disposed in the bottom cover. After that, the top cover 130 is placed to cover the upper side of the frame retaining wall 140. A height of the side frames 120 is smaller than a height of the frame retaining wall 140, and the height of the frame retaining wall 140 can be adjusted based on the size of the plate-shaped objects to be put therein.

The paper packaging box 100 further comprises two spacers 170. The spacers 170 are positioned in the frame retaining wall 140 and disposed on one side nearby the top cover 130. The spacers 170 are utilized for further isolating the adjacent plate-shaped objects to prevent collisions between the adjacent plate-shaped objects. The paper packaging box 100 further comprises a top buffer material 180 and a bottom buffer material 182. The top buffer material 180 is disposed between the spacers 170 and the top cover 130. The bottom buffer material 182 is disposed on the bottom cover 110. In some embodiments, the top buffer material 180 and the bottom buffer material 182 are paper sheet materials, such as a corrugated board, utilized for providing a buffer between the plate-shaped objects and the top cover 130 and a buffer between the plate-shaped objects and the bottom cover 110, respectively.

In the paper packaging box 100, the side frames 120 are fixed on the bottom cover 110 by utilizing Velcro. Hence, the paper packaging box 100 has advantages of quick fixing and assembly. In addition, since a material of the side frames 120 is corrugated board, the spacing between the slots 122 of the side frames 120 is reduced from 20 millimeters to 3 millimeters when compared with the traditional foam material. As a result, the transportation quantity is increased while requirements for supporting strength and energy conservation and carbon reduction are satisfied.

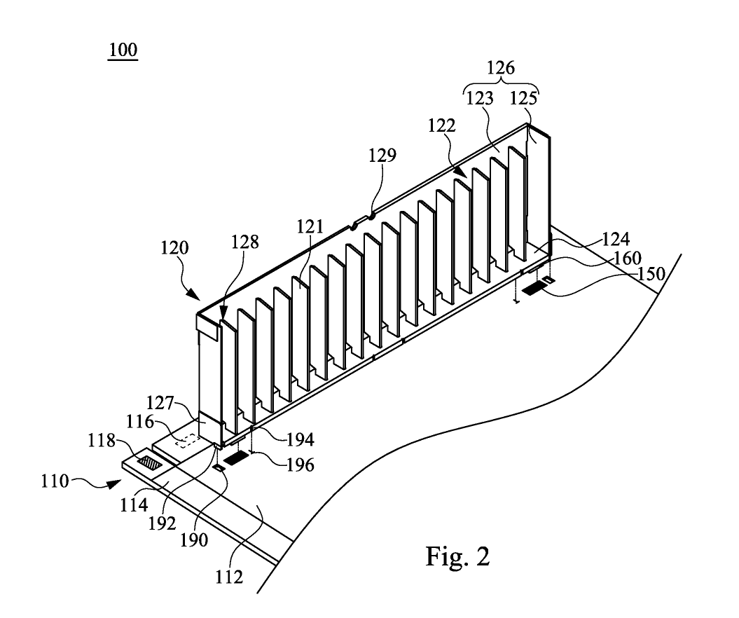

FIG. 2 is a schematic diagram of a paper packaging box when a side frame is assembled with a bottom cover according to one embodiment of the invention. The side frame 120 comprises a bottom plate 124 and a side plate 126 standing on the bottom plate 124. The bottom plate 124 faces the bottom cover 110 and is approximately parallel with the bottom cover 110. The above-mentioned second Velcro portions 160 are disposed on a bottom surface of the bottom plate 124 so as to be connected with the first Velcro portions 150 disposed on the bottom cover 110. The side plate 126 is connected to the bottom plate 124 and is approximately perpendicular to the bottom plate 124. The side plate 126 has a plurality of openings 128, and a shape of the openings 128 is a strip. The side frame 120 further comprises a plurality of first spacing boards 121 disposed approximately perpendicular to the side plate 126. Each of the first spacing boards 121 is parallel with the other first spacing boards 121 and is inserted in one of the openings 128 of the side plate 126. In this manner, the first spacing boards 121 are disposed approximately perpendicular to the side plate 126, and the above-mentioned slot 122 is formed between any of the two adjacent first spacing boards 121.

The bottom plate 124 and the side plate 126 are integrally formed. That is, the bottom plate 124 and the side plate 126 can be formed by one paper sheet, followed by bending the paper sheet. After that, the first spacing boards 121 are inserted into the openings 128 of the side plate 126 to obtain the side frame 120.

The side plate 126 comprises a body 123 and two bending portions 125 respectively connected to opposite ends of the body 123. The two bending portions 125 are also connected to two opposite ends of the bottom plate 124, respectively. Through such a configuration, the side plates 126 of the side frames 120 and the bottom plate 124 form the accommodation spaces. The openings 128 are formed in the body 123. The first spacing boards 121 are approximately parallel with the bending portions 125. The side frame 120 further comprises a plurality of reinforcement sheets 127. The reinforcement sheets 127 are respectively attached to top ends of the body 123 and the bending portions 125 and bottom ends of the body 123 and the bending portions 125 to improve the structural strength of the side plates 126.

At least one center alignment structure 129 is disposed on the side plate 126 of the side frame 120. The center alignment structure 129 may comprise any mark, such as the indentation shown in the figure. The center alignment structure 129 is disposed in such a manner that a position corresponds to one or two of the center slots 122 so as to mark a center position of the side frame 120. With such a configuration, the plate-shaped objects are rapidly and correctly placed to reduce the possibility of misplacement.

The bottom cover 110 has positioning holes 190. The side frame 120 comprises positioning protrusions 192 projecting from the bottom of the bottom plate 124. The positioning holes 190 are engaged with the positioning protrusions 192 so as to position the side frame 120 on the bottom cover 110. The bottom plate 124 of the side frame 120 may further selectively has a plurality of first alignment points 194, and the bottom cover 110 may further selectively has a plurality of second alignment points 196. When the side frame 120 is assembled with the bottom cover 110, the first alignment points 194 are adopted for aligning with the second alignment points 196 so as to position the side frame 120 on the bottom cover 110. The first alignment point 194 and the second alignment point 196 may be any mark.

The bottom cover 110 comprises a base plate 112 and a plurality of extending portions 114 connected to sides of the base plate 112. The base plate 112 and the extending portions 114 are approximately in a rectangular shape. The first Velcro portions 150 are disposed on the base plate 112 of the bottom cover 110. The second Velcro portions 160 are disposed on the bottom plate 124 of the side frame 120. The first Velcro portions 150 and the second Velcro portions 160 are engaged with each other so as to fix the side frame 120 on the bottom cover 110.

The bottom cover 110 further comprises a plurality of third Velcro portions 116 and a plurality of fourth Velcro portions 118 disposed on the extending portions 114. The third Velcro portions 116 and the fourth Velcro portions 118 are disposed in pairs, and each of the third Velcro portions 116 and each of the fourth Velcro portions 118 are respectively positioned close to one end of a lower surface of the extending portion 114 and an adjacent end of an upper surface of the adjacent extending portion 114. With such a configuration, the ends of the adjacent extending portions 114 are fastened to each other through the engagement between the third Velcro portion 116 and the fourth Velcro portion 118 when the extending portions 114 are bent to stand on the base plate 112. The third Velcro portion 116 and the fourth Velcro portion 118 may be a loop portion and a hook portion, respectively.

Hence, after the side frames 120 are assembled with the base plate 112 of the bottom cover 110, the frame retaining wall 140 shown in FIG. 1 is disposed around the outside of the side frames 120. The extending portions 114 are then bended to stand on the base plate 112. After that, the third Velcro portions 116 and the fourth Velcro portions 118 on the extending portions 114 are engaged with each other so that the bottom cover 110 covers the bottom side of the frame retaining wall 140 (see FIG. 1).

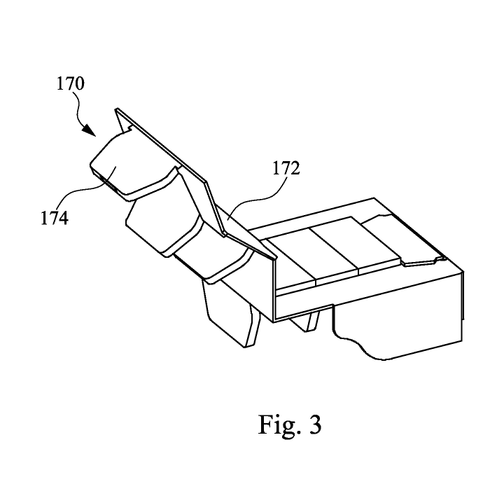

FIG. 3 is a schematic diagram of a spacer 170 in a paper packaging box in service state according to one embodiment of the invention. The spacer 170 comprises a top plate 172 and a plurality of second spacing boards 174 disposed approximately perpendicular to the top plate 172. The second spacing boards 174 are adopted for facing the bottom cover 110 and for further isolating the plate-shaped objects, as shown in FIG. 1. A distance between the two adjacent second spacing boards 174 is approximately equal to a thickness of the plate-shaped objects. The spacer 170 is made of a paper material and has a plurality of fold lines to facilitate the bending of the spacer 170 in the manner shown in the figure so that each of the second spacing boards 174 is positioned between the plate-shaped objects. As a result, collisions between the plate-shaped objects are prevented.

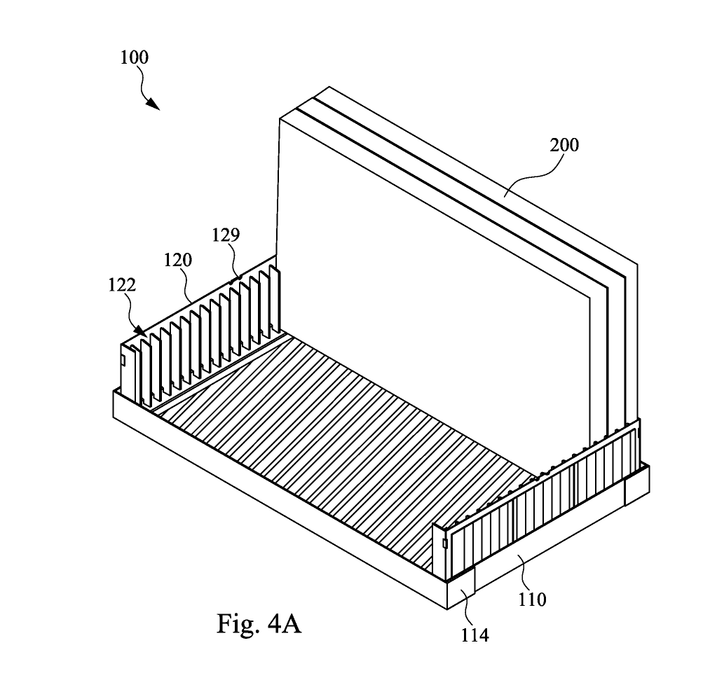

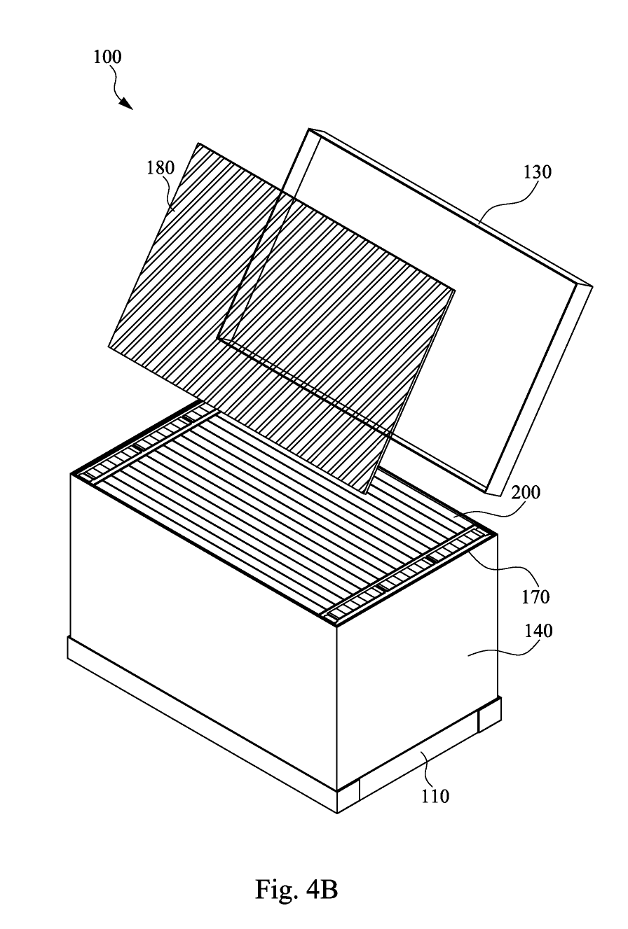

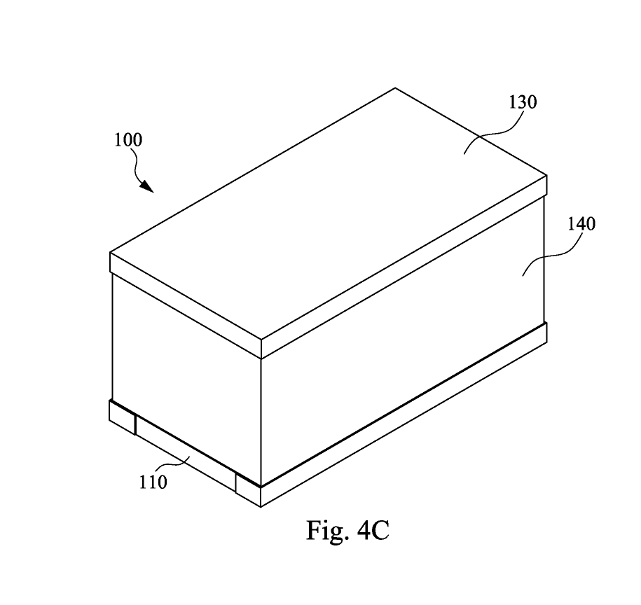

FIG. 4A to FIG. 4C are perspective views of the paper packaging box at different assembly stages according to the invention. As shown in FIG. 4A, the two side frames 120 are respectively positioned on two opposite sides of the bottom cover 110, and the extending portions 114 of the bottom cover 110 are fastened together (the detailed assembly of the bottom cover 110 and the side frames 120 may be referred to FIG. 2). Plate-shaped objects 200 are then placed into the slots 122 of the side frames 120. The plate-shaped object 200 may comprises a solar module or a flat panel display. The plate-shaped objects 200 may be placed into the slots 122 in sequence from one side to another side of the side frames 120 as shown in the figure. Or, the plate-shaped object 200 may be first placed into the slot 122 at the center position of the side frames 120 marked by the center alignment structure 129 shown in FIG. 2.

As shown in FIG. 4B, after the plate-shaped objects 200 are placed into the slots 122 of the side frames 120 sequentially, the frame retaining wall 140 is disposed around the outside of the side frames 120. The spacers 170 shown in FIG. 3 are then inserted into the spacing between the plate-shaped objects 200 to reduce collisions between the plate-shaped objects 200 during transportation. After that, the top buffer material 180 is positioned on top of the plate-shaped objects 200 and the spacers 170 followed by covering the frame retaining wall 140 with the top cover 130.

As shown in FIG. 4C, the top cover 130 and the bottom cover 110 of the assembled paper packaging box 100 are positioned on two opposite sides of the frame retaining wall 140, respectively.

Or, in other embodiments, after the side frames 120 are fastened onto the bottom cover 110, the plate-shaped objects 200 to be fixed and the spacers 170 utilized for spacing apart the plate-shaped objects 200 are placed. The frame retaining wall 140 is then disposed around the outside of the side frames 120. After that, the extending portions 114 of the bottom cover 110 are fastened together through the engagement between the third Velcro portions 116 (see FIG. 2) and the fourth Velcro portions 118 (see FIG. 2) to allow the bottom cover 110 to cover the frame retaining wall 140. Finally, the top buffer material 180 is positioned on top of the plate-shaped objects 200 followed by covering the frame retaining wall 140 with the top cover 130.

According to above embodiments, the step of inserting the frame retaining wall 140 into the bottom cover 110 is omitted because the bottom cover 110 is assembled through the engagement between the third Velcro portions 116 (see FIG. 2) and the fourth Velcro portions 118 (see FIG. 2) after the frame retaining wall 140 is disposed around the outside of the side frames 120 and the plate-shaped objects 200. In this manner, the assembly efficiency is improved.

In summary, the present invention paper packaging box is made of a hard paper material, such as corrugated board. Not only is the present invention paper packaging box environmentally friendly, but the transportation quantity is also increased owing to the reduced spacing between the slots. In addition, since the paper packaging box is assembled by utilizing Velcro, it has the advantages of easy assembly and simple placement.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A paper packaging box, comprising:
a bottom cover;
two side frames respectively disposed standing on two opposite sides of the bottom cover, each of the side frames comprising a plurality of slots, and the slots of the two side frames being disposed face to face in pairs;
a plurality of first Velcro portions disposed at the bottom cover;
a plurality of second Velcro portions disposed at the side frames, the first Velcro portions and the second Velcro portions being engaged with each other to allow the side frames to stand on the bottom cover; and
a top cover disposed above the side frames.

2. The paper packaging box of claim 1, wherein each of the side frames comprises:
a bottom plate;
a side plate standing on the bottom plate; and
a plurality of first spacing boards disposed approximately perpendicular to the side plate, each of the first spacing boards being approximately parallel with the other first spacing boards, and the slots being formed between the adjacent first spacing boards.

3. The paper packaging box of claim 2, wherein the bottom plate and the side plate are integrally formed.

4. The paper packaging box of claim 2, wherein the side plate comprises a body and two bending portions, one ends of the two bending portions are respectively connected to opposite ends of the body, another ends of the two bending portions are respectively connected to two opposite ends of the bottom plate.

5. The paper packaging box of claim 2, wherein the side frame comprises at least one reinforcement sheet attached to top ends of the body and the bending portions or bottom ends of the body and the bending portions.

6. The paper packaging box of claim 2, wherein the bottom cover has a positioning hole, the side frame comprises a positioning protrusion projecting from the bottom plate, the positioning hole is utilized for engaging with the positioning protrusion.

7. The paper packaging box of claim 2, wherein the second Velcro portions are disposed at the bottom plate of the side frame.

8. The paper packaging box of claim 2, wherein the bottom plate has a plurality of first alignment points, the bottom cover has a plurality of second alignment points, the second alignment points are utilized for respectively aligning with the first alignment points so as to position the side frame on the bottom cover.

9. The paper packaging box of claim 2, wherein the side plate of the side frame has at least one center alignment structure, the center alignment structure is disposed in such a manner that a position of the center alignment structure corresponds to at least one center slot of the slots.

10. The paper packaging box of claim 1, wherein the bottom cover comprises:
a base plate, the first Velcro portions being disposed on the base plate;
a plurality of extending portions connected to sides of the base plate; and
a plurality of third Velcro portions and a plurality of fourth Velcro portions, each of the third Velcro portions and each of the fourth Velcro portions being respectively disposed close to one end of a lower surface of the extending portion and an adjacent end of an upper surface of the adjacent extending portion to allow the adjacent extending portions to be fastened to each other when the extending portions are bent to stand on the sides of the base plate.

11. The paper packaging box of claim 10, further comprising a frame retaining wall utilized for being disposed around the outside of the side frames.

12. The paper packaging box of claim 10, wherein a height of the frame retaining wall is greater than a height of the side frames.

13. The paper packaging box of claim 11, wherein the top cover and the bottom cover respectively are adopted for respectively covering two opposite sides of the frame retaining wall.

14. The paper packaging box of claim 13, further comprising two spacers disposed in the frame retaining wall, each of the spacers comprising a top plate and a plurality of second spacing boards disposed approximately perpendicular to the top plate, accommodation spaces corresponding to the slots of the side frame being formed between the adjacent second spacing boards.

15. The paper packaging box of claim 14, further comprising a top buffer material and a bottom buffer material, wherein the top buffer material is disposed between the spacers and the top cover, and the bottom buffer material is disposed on the bottom cover.
